(19) United States
(12) Patent Application Publication
(10) Pub. No.: US 2015/0288916 A1
(43) Pub. Date: Oct. 8, 2015

(54) INTEGRATED CIRCUIT DEVICE AND IMAGE PROCESSING APPARATUS

(71) Applicant: CANON KABUSHIKI KAISHA, Tokyo (JP)

(72) Inventor: Takaaki Yokoi, Kawasaki-shi (JP)

(21) Appl. No.: 14/678,256

(22) Filed: Apr. 3, 2015

(30) Foreign Application Priority Data
Apr. 7, 2014 (JP) 2014-078979

(51) Int. Cl. H04N 5/77; H01L 27/146

(52) U.S. Cl. CPC H04N 5/772; H01L 27/14621; H01L 27/14634; H01L 27/14636

(57) ABSTRACT

An integrated circuit device comprises a first integrated circuit chip; and a plurality of second integrated circuit chips each stacked on the first integrated circuit chip, wherein the first integrated circuit chip includes a plurality of first connection portions for respectively connecting to the second integrated circuit chips, the second integrated circuit chips each includes a second connection portion that is connected to one of the first connection portions of the first integrated circuit chip, and the second integrated circuit chips are arranged on the same surface of the first integrated circuit chip, such that the same signal is output from the first connection portions of the first integrated circuit chip to the respective second connection portions of the plurality of second integrated circuit chips.

### BACKGROUND OF THE INVENTION

1. Field of the Invention

The present invention relates to an integrated circuit device that is constituted by stacking a plurality of integrated circuit chips.

2. Description of the Related Art

Advances in semiconductor technology are seeing a rapid increase in the number of pixels on image sensors that are used in digital still cameras, video cameras, and the like. The amount of information to be processed by LSIs (integrated circuits) for image processing that perform camera signal processing and encoding on subject images formed on the image sensor has also increased rapidly with this increase in the number of pixels, resulting in the increasing size of image processing LSIs.

However, the dimensions required to integrate components on one chip have increased markedly with limitations to miniaturization and increases in the number of the functions to be implemented, and integration on one chip, as has previously been the case, is no longer necessarily the optimal solution.

In view of this, a method has been proposed in which a plurality of image processing LSIs are provided, and image signals that are output from the image sensor are divided and processed by the plurality of image processing LSIs. However, with this method, the wiring length increases in order to connect the image signal output from the image sensor to the plurality of integrated circuit chips, making it difficult to increase the transmission speed.

In order to solve such problems, a method of stacking a plurality of devices three-dimensionally using through vias has been proposed (see Japanese Patent Laid-Open No. 2010-109264). By using such a stacking method, the wiring length is shortened and transmission speed can be improved. Also, the size of the mount board within the image capturing apparatus can be reduced by stacking a plurality of devices, enabling miniaturization of the image capturing apparatus to be realized.

However, in the case where image signals output from the image sensor are divided and processed by a plurality of LSI chips, special configurations are required, such as adding and fabricating through-silicon vias (TSVs) for stacking a plurality of integrated circuit chips.

### SUMMARY OF THE INVENTION

The present invention has been made in consideration of the above problems, and enables image signals output from an image sensor to be divided and processed by a plurality of integrated circuits, in the case where a plurality of integrated circuit chips are stacked, without adding dedicated circuitry for implementing the stacking.

In order to solve the aforementioned problems, the present invention provides an integrated circuit device comprising: a first integrated circuit chip; and a plurality of second integrated circuit chips each stacked on the first integrated circuit chip, wherein the first integrated circuit chip includes a plurality of first connection portions for respectively connecting to the second integrated circuit chips, the second integrated circuit chips each includes a second connection portion that is connected to one of the first connection portions of the first integrated circuit chip, and the second integrated circuit chips are arranged on the same surface of the first integrated circuit chip, such that the same signal is output from the first connection portions of the first integrated circuit chip to the respective second connection portions of the plurality of second integrated circuit chips.

In order to solve the aforementioned problems, the present invention provides an image processing apparatus comprising: an image processing circuit that performs predetermined processing on image data that is output from an image sensor; and a control unit that controls output of the image data from the image sensor to the image processing circuit, wherein the image sensor and the image processing circuit are provided as different integrated circuit chips, the integrated circuit chip of the image sensor includes a first connection portion for connecting to each of a plurality of integrated circuit chips of the image processing circuit, the integrated circuit chips of the image processing circuit each includes a second connection portion that is connected to one of the first connection portions of the integrated circuit chip of the image sensor, and the plurality of integrated circuit chips of the image processing circuit are arranged on the same surface of the integrated circuit chip of the image sensor, such that the same signal is output from the first connection portions of the integrated circuit chip of the image sensor to the respective second connection portions of the plurality of integrated circuit chips of the image processing circuit.

According to the present invention, image signals output from an image sensor can be divided and processed by a plurality of integrated circuits, in the case where a plurality of integrated circuit chips are stacked, without adding dedicated circuitry for implementing the stacking.

Further features of the present invention will become apparent from the following description of exemplary embodiments (with reference to the attached drawings).

### BRIEF DESCRIPTION OF THE DRAWINGS

FIG. 1 is a block diagram showing a configuration of an image processing apparatus according to a first embodiment.

FIGS. 2A to 2D are diagrams showing a stacked structure of an image sensor and image processing LSIs.

FIG. 3 is a diagram showing a pixel array of the image sensor.

FIG. 4 is a diagram showing image data that is output from the image sensor to the image processing LSIs.

FIG. 5 is a diagram showing the timing of image data processing by the image processing LSIs of the first embodiment.

FIGS. 6A and 6B are diagrams showing another stacked structure of an image sensor and image processing LSIs.

FIGS. 7A to 7C are diagrams showing another stacked structure of an image sensor and image processing LSIs.

FIG. 8 is a block diagram showing the configuration of an image processing apparatus according to a second embodiment.

FIG. 9 is a diagram showing the timing of image data processing by the image processing LSIs of the second embodiment.

### DESCRIPTION OF THE EMBODIMENTS

Embodiments of the present invention will be described in detail below. The following embodiments are merely examples for practicing the present invention. The embodiments should be properly modified or changed depending on various conditions and the structure of an apparatus to which the present invention is applied. The present invention should not be limited to the following embodiments. Also, parts of the embodiments to be described later may be properly combined.

### First Embodiment

Hereinafter, an embodiment in which an image processing apparatus of the present invention is applied to, for example, an image capturing apparatus such as a digital video camera that captures moving images and still images will be described.

Apparatus Configuration

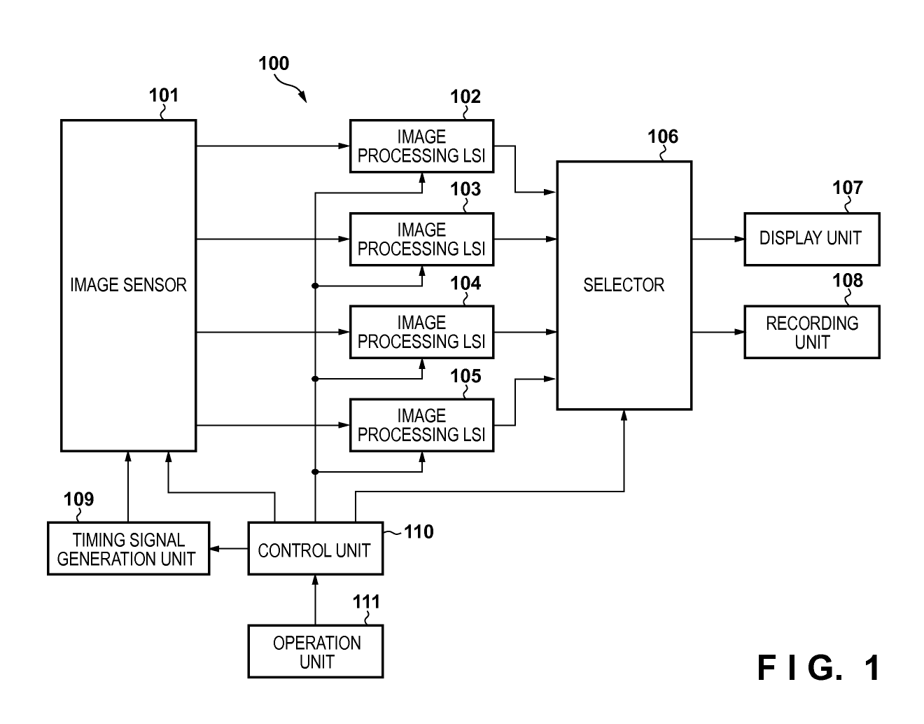

An overview of the configuration and functions of the image capturing apparatus of the first embodiment according to the present invention will be described, with reference to FIG. 1.

In FIG. 1, an image sensor 101 is configured by a plurality of pixels each composed of a well-known photoelectric conversion circuit such as a CMOS or the like being arranged two-dimensionally. The image sensor 101, which is constituted by, for example, 3840 horizontal pixels×2160 vertical pixels, performs photoelectric conversion in accordance with operation timing signals from a timing signal generation unit 109 and outputs image data. The image sensor 101 can output moving image data at 60 frames per second and 3840 horizontal pixels×2160 vertical pixels per screen. The image sensor 101 is constituted as a single semiconductor integrated circuit chip.

Image signals that are output from the image sensor 101 are supplied to image processing LSIs 102 to 105. The image processing LSIs 102 to 105 are each constituted as a single semiconductor integrated circuit chip. Also, the image processing LSIs 102 to 105 are image processing circuits each having the same configuration. The image processing LSIs 102 to 105 each perform development processing such as pixel interpolation, filtering and color conversion on the image signals output from the image sensor 101. Also, the image processing LSIs 102 to 105 each perform resizing according to the display size of a display unit 107 on image data that has undergone development processing, and output the resultant image data to a selector 106. Also, the image processing LSIs 102 to 105 each perform image processing required in order to record the image data, such as encoding by a well-known encoding method such as H.264 encoding, compression and the like, and output the resultant image data to the selector 106.

The selector 106 selects image data output from the image processing LSIs 102 to 105 in accordance with an instruction from a control unit 110, and outputs the selected image data to the display unit 107 and a recording unit 108.

The timing signal generation unit 109 generates a signal, such as a vertical synchronizing signal, indicating the operation timing of each unit of the image capturing apparatus 100. The control unit 110 has a CPU and a memory, and controls the units of the image capturing apparatus 100 in accordance with instructions from an operation unit 111. The operation unit 111 is provided with various types of operation switches such as a power switch and buttons for instructing to start and stop recording. The user can input various types of instructions to the image capturing apparatus 100 by operating the operation unit 111.

Configuration of Image Processing LSIs

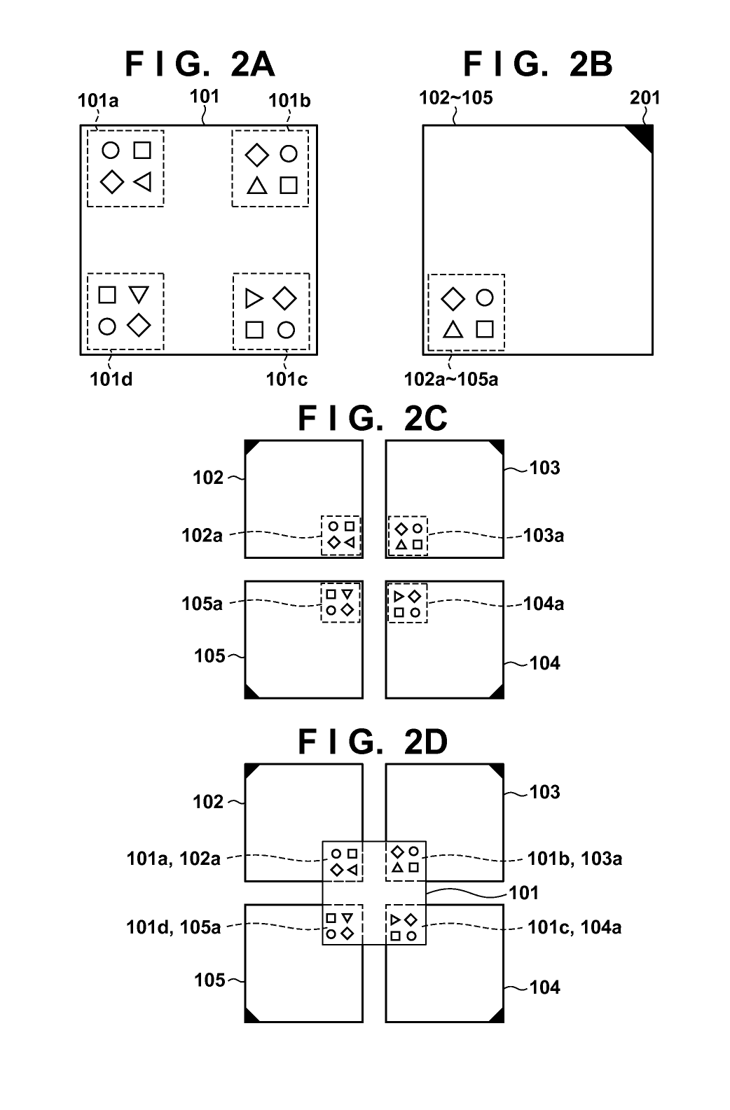

Next, the configuration of the image sensor 101 and the image processing LSIs 102 to 105 that are mounted in the image capturing apparatus 100 of the present embodiment will be described, with reference to FIGS. 2A to 2D.

FIG. 2A shows connection terminals, arranged in the image sensor 101, that are for connecting to the image processing LSIs 102 to 105. In FIG. 2A, sets of connection terminals 101a to 101d for connecting to the image processing LSIs 102 to 105 are arranged on one surface of the semiconductor chip constituting the image sensor 101. Symbols O, □, ⋄ and Δ represent the types of connection terminal for each piece of data that is output to the image processing LSIs 102 to 105, and the symbols O, □, ⋄ and Δ within the dotted lines are respectively connected to the image processing LSIs 102 to 105 as one set.

In the present embodiment, in order to connect to the four image processing LSIs 102 to 105, the image sensor 101 is provided with four sets of connection terminals 101a to 101d. Also, these sets of connection terminals 101a to 101d are arranged such that the respective connections of O, □, ⋄ and Δ are in a symmetrical positional relationship about the center of the image sensor 101.

FIG. 2B shows connection terminals, arranged in each of the image processing LSIs 102 to 105, that are for connecting to the image sensor 101. In FIG. 2B, one set of connection terminals 102a to 105a for connecting to the image sensor 101 are arranged on one surface of the semiconductor chip constituting each of the image processing LSIs 102 to 105. Note that reference numeral 201 is a mark included in order to indicate the rotation direction when the image processing LSIs 102 to 105 are arranged.

FIG. 2C shows the arrangement of the image processing LSIs 102 to 105 at the time of stacking on the image sensor 101. In the present embodiment, as shown in FIG. 2C, the image processing LSIs 102 to 105 are arranged next to each other in the same plane. At this time, the image processing LSIs 102 to 105 are each rotated 90 degrees, and arranged so that the sets of connection terminals 102a to 105a face each other. The image sensor 101 is stacked on the image processing LSIs 102 to 105 arranged in this way.

FIG. 2D shows a state in which the image sensor 101 is stacked on the image processing LSIs 102 to 105 arranged as shown in FIG. 2C. The image sensor 101 and the image processing LSIs 102 to 105 are stacked such that the sets of connection terminals 101a to 101d of the image sensor 101 respectively overlap the sets of connection terminals 102a to 105a of the image processing LSIs 102 to 105.

Image Data Output to Image Processing LSIs

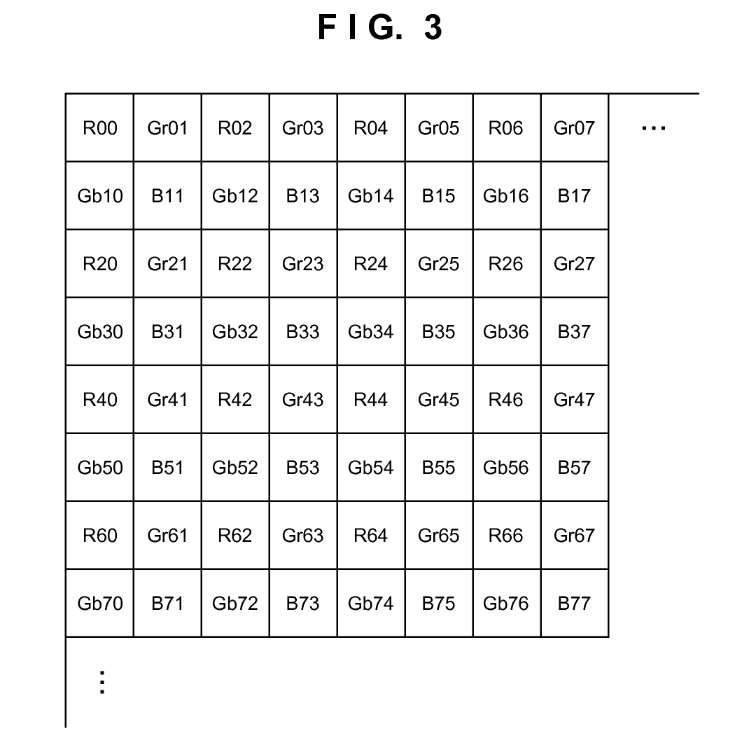

Next the image data that is output to the image processing LSIs from the connection terminals of the image sensor 101 will be described, with reference to FIG. 3.

FIG. 3 shows the pixel configuration of the image sensor 101. In the image sensor 101, color filters of four colors R, Gr, Gb and B shown in FIG. 3 are arranged in a reticular pattern on the pixels. Data of the pixels of the image sensor 101 is output such that R pixel data is output from the terminals represented by the symbol O, Gr pixel data is output from the terminals represented by the symbol □, Gb pixel data is output from the terminals represented by the symbol ⋄, and B pixel data is output from the terminals represented by the symbol Δ. Also, the same image data is output simultaneously from each set of the connection terminals 102a to 105a to the image processing LSIs 102 to 105 stacked on the image sensor 101.

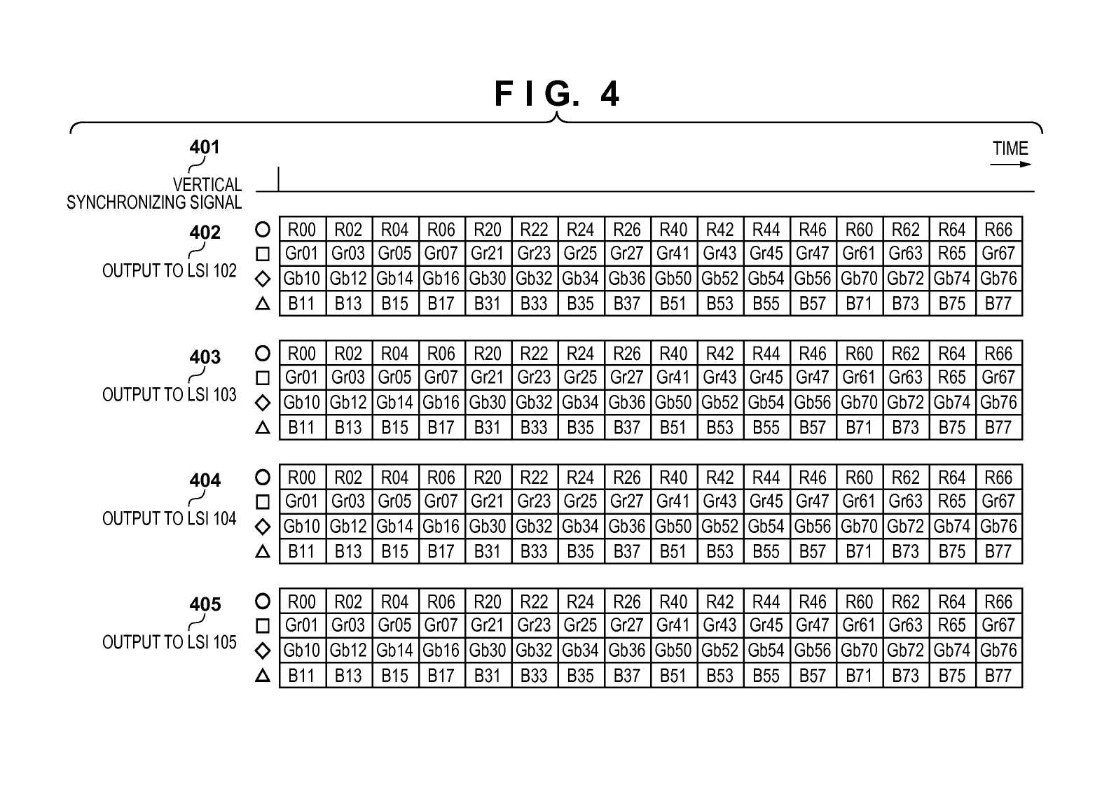

FIG. 4 shows the output timing of image data that is output from the image sensor 101 to the image processing LSIs 102 to 105 as the output timing of the image data of one screen (one frame).

Reference numeral 401 denotes the vertical synchronizing signal from the timing signal generation unit 109. Image data is output from the image sensor 101 in synchronization with this vertical synchronizing signal 401. Also, reference numerals 402 to 405 respectively denote image data that is output to the connection terminals O, □, ⋄ and Δ of the image processing LSIs 102 to 105.

That is, in the present embodiment, image data of the four colors R, Gr, Gb and B is output, in raster scan order, in parallel to one image processing LSI on the basis of the vertical synchronizing signal. Also, the same image data is output in parallel to each of the image processing LSIs 102 to 105.

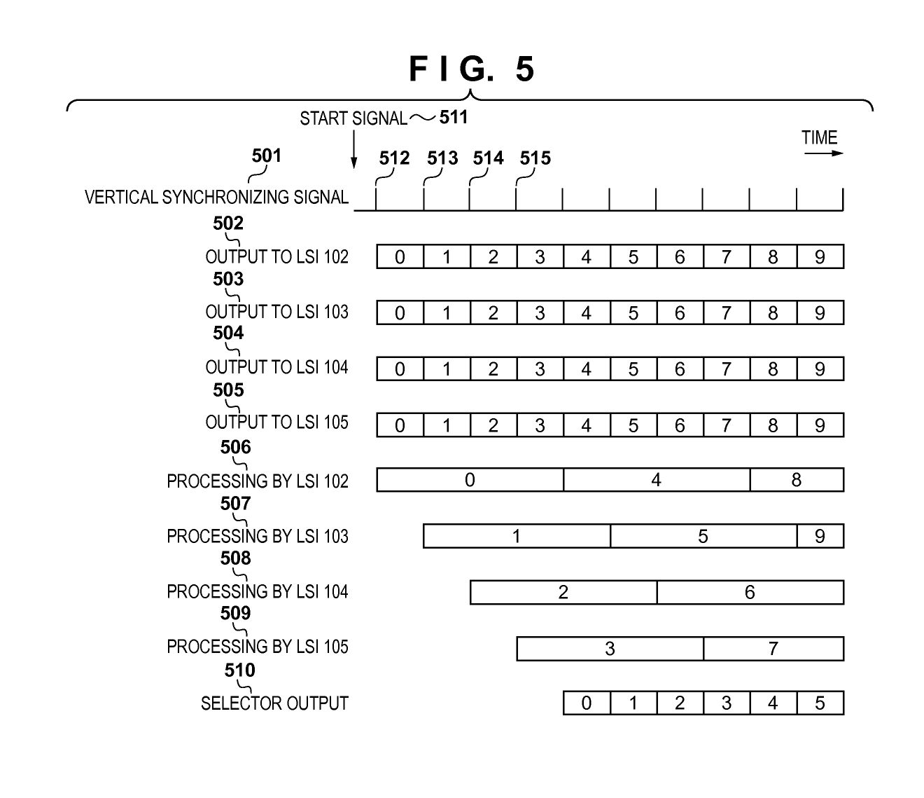

FIG. 5 shows the timing of processing by the image processing LSIs 102 to 105 in the case where the image processing LSIs 102 to 105 process a plurality of frames of moving image data that is continuously output from the image sensor 101.

In the present embodiment, the image processing LSIs 102 to 105 perform time sharing processing on the moving image data that is output from the image sensor 101. That is, after the image capturing apparatus has been powered on using the operation unit 111, the control unit 110 controls the timing signal generation unit 109 to start generation of a vertical synchronizing signal 501. The vertical synchronizing signal 501 from the timing signal generation unit 109 is supplied to the image sensor 101. Next, the control unit 110 outputs a start signal 511 indicating the start of processing to the image processing LSIs 102 to 105. The image processing LSIs 102 to 105 each detects a frame to be processed by the respective image processing LSIs 102 to 105, based on the start signal 511. Also, the image processing LSIs 102 to 105 each have a built-in timer for determining the operation timing based on an operation clock from the timing signal generation unit 109. The image processing LSIs 102 to 105 respectively generate timing signals in a four frame cycle 512 to 515, based on the output of the timer. At this timing of four frame cycles, the image processing LSIs 102 to 105 each input one frame of image data that is output from the image sensor 101, and process the input frame of image data within a three frame period. That is, the image processing LSIs 102 to 105 input and process image data at a rate of one frame every four frames. Note that the image processing LSIs 102 to 105 are each provided with a memory such as an SDRAM, and process the input frame of image data after initially storing the image data in the memory.

In FIG. 5, reference numeral 501 denotes the vertical synchronizing signal from the timing signal generation unit 109. Reference numerals 502 to 505 respectively denote the frame numbers of the moving image data that is output to the image processing LSIs 102 to 105. As shown by reference numerals 502 to 505, the same image data is output in parallel from the image sensor 101 to each of the image processing LSIs 102 to 105.

Reference numerals 506 to 509 respectively denote the frames that are processed by the image processing LSIs 102 to 105. For example, the start signal 511 is output from the control unit 110 to each of the image processing LSIs 102 to 105 at the timing shown in FIG. 5. In the case where processing is performed one frame at a time in order from the image processing LSI 102, the image processing LSI 102 inputs the image data of frame number 0 that is output from the image sensor 101 in response to the vertical synchronizing signal 512 following the start signal 511 (502). Thereafter, the image processing LSI 102 processes the image data of frame number 0 within a three frame period (506). The image processing LSI 103 similarly inputs the image data of frame number 1 that is output from the image sensor 101 in response to the second vertical synchronizing signal 513 after the start signal 511 (503), and processes the image data within a three frame period (507). Similarly, the image processing LSIs 104 and 105 also respectively input the image data of frame numbers 2 and 3 that is output from the image sensor 101 in response to the vertical synchronizing signals 514 and 515 (504, 505), and process the image data (508, 509).

The image processing LSIs 102 to 105 each thereafter input and process the data of one readout cycle every four readout cycles of frames of image data by the image sensor 101, based on the internal timing signals that are generated in a four frame cycle.

The control unit 110 controls the selector 106, such that the image data processed by each of the image processing LSIs 102 to 105 is sequentially switched to and output every one frame. Reference numeral 510 denotes moving image data that is output from the selector 106.

As described above, by using an image sensor that is capable of outputting the same data in parallel to a plurality of image processing LSIs, the wiring length can be shortened and the transmission speed can be increased in the case where time sharing processing is performed with a plurality of image processing LSIs.

Also, by providing connection portions that can connect to the plurality of image processing LSIs in the image sensor and connecting the image processing LSIs, it is possible to stack the image sensor and the plurality of image processing LSIs, without mounting additional circuitry for implementing the stacking.

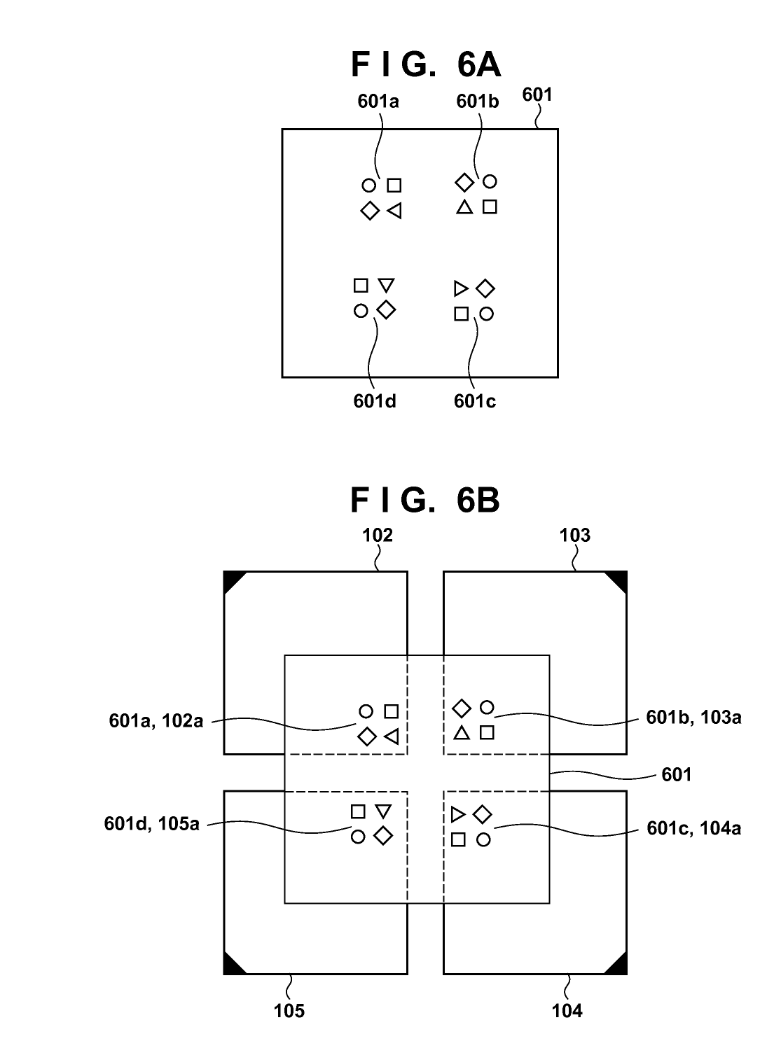

Note that, in the present embodiment, the dimensions of the semiconductor chip of the image sensor 101 are smaller than the chip dimensions of each image processing LSI. The present invention is similarly applicable, even if, alternatively, the dimensions of the semiconductor chip of the image sensor 101 are larger than the chip dimensions of each image processing LSI. In this case, the plurality of image processing LSIs 102 to 105 are arranged on the same surface of the image sensor 101, for example, as shown in FIG. 2D. On the other hand, in an image sensor 601, as shown in FIG. 6A, four sets of connection terminals 601a to 601d are arranged in positions that respectively contact the sets of connection terminals of the image processing LSIs 102 to 105, when the image sensor 601 is stacked on the image processing LSIs 102 to 105. As a result, the same number of image processing LSIs-102 to 105 as the number of sets of connection terminals 601a to 601d of the image sensor 601 can be arranged on the same surface of the image sensor 601, as shown in FIG. 6B, even when the size of the image sensor 601 and the size of the image processing LSIs change.

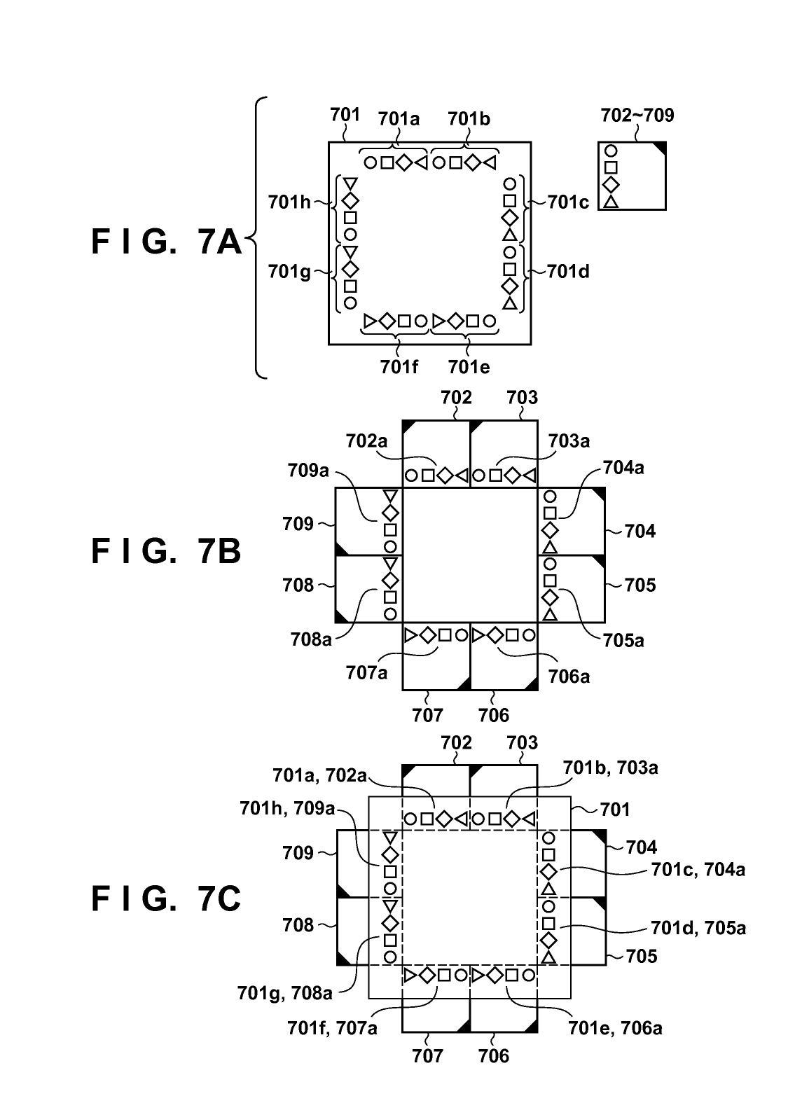

The number of image processing LSIs that can be arranged on the same surface of the image sensor is determined according to the relationship between the chip dimensions of the image sensor and the image processing LSIs, and the arrangement and number of sets of connection terminals. For example, in the case where the dimensions of the image processing LSIs are considerably smaller compared to the chip dimensions of the image sensor, it is possible to arrange five or more image processing LSIs on the same surface of the image sensor 101, by arranging sets of connection terminals along each side of the chip of the image sensor as shown in FIGS. 7A to 7C. For example, in the case where the chip dimensions of the image sensor 701 are large compared to image processing LSIs 702 to 709, sets of connection terminals 701a to 701h are provided two along each side, as shown in FIG. 7A. As shown in FIG. 7C, the eight image processing LSIs 702 to 709 in which set of connection terminals 702a to 709a are respectively arrayed as shown in FIG. 7B are arranged on the same surface of the image sensor 701.

By arranging the image processing LSIs 702 to 709 so as to partially not overlap the image sensor 701, the effect of enabling heat that is generated by the image processing LSIs to be dissipated is also obtained at this time.

### Second Embodiment

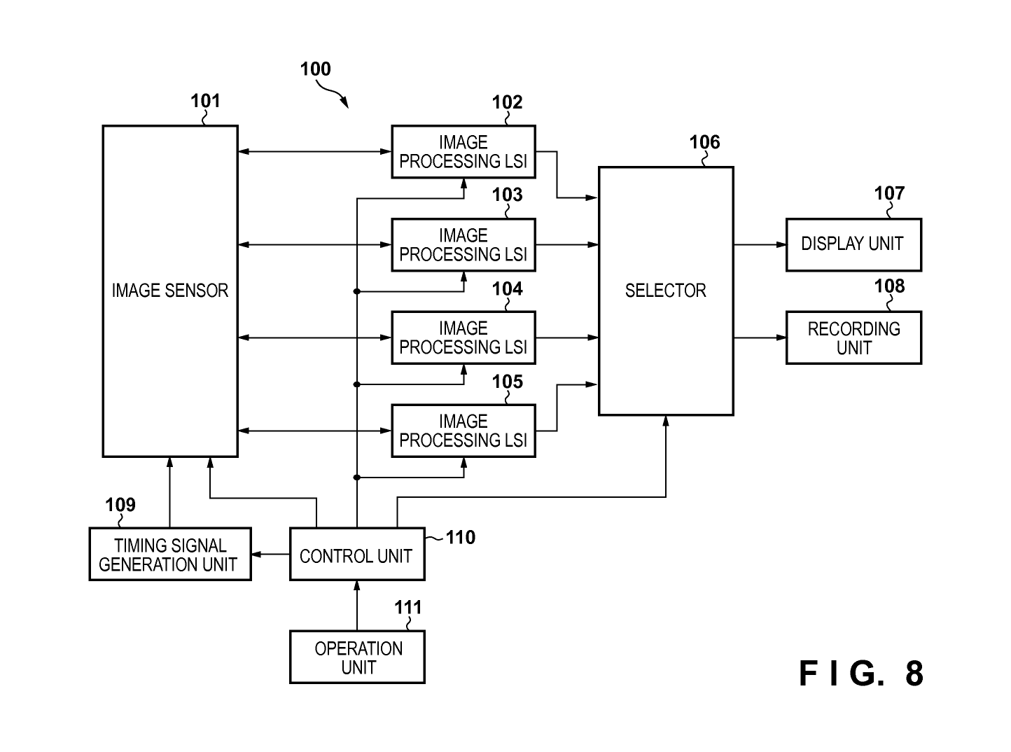

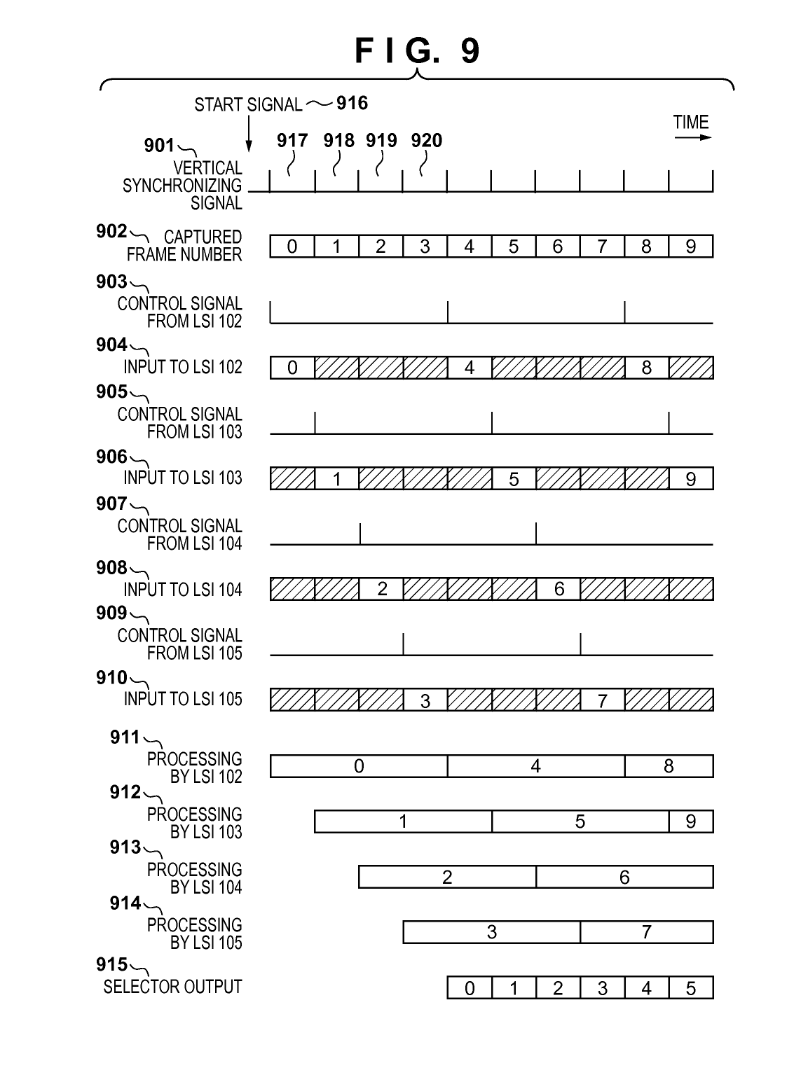

Next, an image processing apparatus of a second embodiment will be described, with reference to FIGS. 8 and 9.

In the first embodiment, image data was simultaneously supplied from the image sensor 101 to the image processing LSIs 102 to 105, and image data was input at the timing at which the individual image processing LSIs 102 to 105 performed processing.

In contrast, in the present embodiment, each of the image processing LSIs 102 to 105 output, to the image sensor 101, a control signal indicating the timing for outputting image data. The image sensor 101 determines the output timing of image data to the image processing LSIs 102 to 105 in accordance with the control signals from the image processing LSIs 102 to 105.

FIG. 8 shows the configuration of the image capturing apparatus 100 of the second embodiment, with control signals being output from the image processing LSIs 102 to 105 to the image sensor 101. The remaining configuration is the same as FIG. 1.

FIG. 9 shows the timing of processing by the image processing LSIs 102 to 105 in the case where the image processing LSIs 102 to 105 process a plurality of frames of moving image data that is continuously output from the image sensor 101.

In FIG. 9, reference numeral 901 denotes the vertical synchronizing signal from the timing signal generation unit 109. Reference numeral 902 denotes the frame numbers of a moving image captured by the image sensor 101. Also, reference numerals 903, 905, 907 and 909 respectively denote control signals indicating the output timing of image data that are output from the image processing LSIs 102 to 105 to the image sensor 101. Also, reference numerals 904, 906, 908 and 910 respectively denote the frame numbers of image data that is input to the image processing LSIs 102 to 105.

For example, a start signal 916 is output from the control unit 110 to the image processing LSIs 102 to 105 at the timing shown in FIG. 9. In the case where processing is performed one frame at a time in order from the image processing LSI 102, the image processing LSI 102 generates an internal timing signal in a four frame cycle as described above. Also, the image processing LSIs 102 to 105 each detect the vertical synchronizing signal 901 that is supplied from the image sensor 101 via the connection terminals. When the vertical synchronizing signal following the start signal 916 is input from the image sensor 101, the control signal 903 for instructing output of image data is output to the image sensor 101. At this time, the image processing LSI 102 outputs the control signal 903 to the image sensor 101 using a predetermined one of the four connection terminals connected to the image sensor 101. Also, in the present embodiment, the control signal 903 is output from the image processing LSI 102 to the image sensor 101 during a vertical blanking period between frames.

The image sensor 101, in response to the control signal 903 from the image processing LSI 102, outputs image data to the image processing LSI 102 during the period of one frame from when this control signal 903 is received until when the next vertical synchronizing signal is input. In FIG. 9, the image data of frame number 0 is output to the image processing LSI 102 in a period 917 (904). The image processing LSI 102 processes the image data of frame number 0 within the following three frame period (911). The image processing LSI 103 similarly outputs the control signal 905 to the image sensor 101 upon detecting the second vertical synchronizing signal after the start signal 916. The image processing LSI 103 then inputs the image data of frame number 1 in a period 918 (906), and processes the image data within a three frame period (912). Similarly, the image processing LSIs 104 and 105 also respectively output the control signals 907 and 909 to the image sensor 101, and input (908, 910) and process (913, 914) the image data of frame numbers 2 and 3 in periods 919 and 920. Reference numeral 915 denotes moving image data that is output from the selector 106.

The image processing LSIs 102 to 105 each thereafter determine the output timing of the control signal to the image sensor 101 by counting the vertical synchronizing signals. The image processing LSIs 102 to 105 each then input and process the data of one readout cycle every four readout cycles of frames of image data by the image sensor 101. In other words, the control unit 110 determines the processing cycle of data according to the number of image processing LSIs relative to the image sensor 101.

Although the present invention has been described taking a stacked structure of an image sensor and image processing LSIs consisting of semiconductor integrated circuit chips that are mounted in an image capturing apparatus such as a digital camera as an example in the abovementioned embodiments, the present invention is not limited thereto, and is applicable to any apparatus having a structure in which one first integrated circuit chip has a plurality of second integrated circuit chips stacked thereon.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-078979, filed Apr. 7, 2014 which is hereby incorporated by reference herein in its entirety.

What is claimed is:

1. An integrated circuit device comprising:
a first integrated circuit chip; and
a plurality of second integrated circuit chips each stacked on the first integrated circuit chip,
wherein the first integrated circuit chip includes a plurality of first connection portions for respectively connecting to the second integrated circuit chips,
the second integrated circuit chips each includes a second connection portion that is connected to one of the first connection portions of the first integrated circuit chip, and
the second integrated circuit chips are arranged on the same surface of the first integrated circuit chip, such that the same signal is output from the first connection portions of the first integrated circuit chip to the respective second connection portions of the plurality of second integrated circuit chips.

2. The device according to claim 1, wherein
the first connection portions and the second connection portions each includes a plurality of connection terminals for transmitting the same type of signal, and
the plurality of first connection portions are arranged on the same surface of the first integrated circuit chip.

3. The device according to claim 1, wherein
the number of second integrated circuit chips that are arranged on the same surface of the first integrated circuit chip is determined according to the number of connection terminals of the first connection portions of the first integrated circuit chips.

4. The device according to claim 1, wherein
the first connection portions are arranged symmetrically with respect to each other on the same surface of the first integrated circuit chip.

5. The device according to claim 1, wherein
the dimensions of the second integrated circuit chips are larger than the dimensions of the first integrated circuit chip.

6. The device according to claim 1, wherein
the dimensions of the second integrated circuit chips are smaller than the dimensions of the first integrated circuit chip.

7. The device according to claim 1, wherein
the first integrated circuit chip has an image sensor, and the second integrated circuit chips have an image processing circuit for processing an image signal that is output from the image sensor.

8. The device according to claim 7, wherein
different color filters are respectively arranged on the pixels of the image sensor, and
data of the pixels of the image sensor is output from the connection terminals of the first connection portions to the connection terminals, each of which corresponds to each pixel of the image sensor, of the second connection portion of each second integrated circuit chip.

9. The device according to claim 8, wherein
the data of each pixel is simultaneously output from the first integrated circuit chip to each of the second integrated circuit chip.

10. The device according to claim 8, wherein
image data is output to the second integrated circuit chips from the first integrated circuit chip, according to a control signal that is output for each of the second integrated circuit chips.

11. The device according to claim 10, wherein
the data is a plurality of frames of moving image data that is continuously output from the image sensor.

12. An image processing apparatus comprising:
an image processing circuit that performs predetermined processing on image data that is output from an image sensor; and
a control unit that controls output of the image data from the image sensor to the image processing circuit,
wherein the image sensor and the image processing circuit are provided as different integrated circuit chips,
the integrated circuit chip of the image sensor includes a first connection portion for connecting to each of a plurality of integrated circuit chips of the image processing circuit,
the integrated circuit chips of the image processing circuit each includes a second connection portion that is connected to one of the first connection portions of the integrated circuit chip of the image sensor, and
the plurality of integrated circuit chips of the image processing circuit are arranged on the same surface of the integrated circuit chip of the image sensor, such that the same signal is output from the first connection portions of the integrated circuit chip of the image sensor to the respective second connection portions of the plurality of integrated circuit chips of the image processing circuit.

13. The apparatus according to claim 12, wherein
the control unit determines a processing cycle of image data according to the number of image processing circuits relative to the image sensor.
